(19) United States
(12) Patent Application Publication
(10) Pub. No.: US 2025/0321253 A1
(43) Pub. Date: Oct. 16, 2025

(54) ELECTRIC POWER DATA COLLECTION DEVICE AND PROCESS OF IMPLEMENTING THE SAME

(71) Applicant: Power Monitors, Inc., Mt. Crawford, VA (US)

(72) Inventors: Walter Morgan CURT, Mt. Crawford, VA (US); Christopher Fisher MULLINS, Mt. Crawford, VA (US)

(21) Appl. No.: 19/060,942

(22) Filed: Feb. 24, 2025

Related U.S. Application Data
(60) Provisional application No. 63/557,324, filed on Feb. 23, 2024.

(51) Int. Cl. G01R 22/06; G01R 27/26

(52) U.S. Cl. CPC G01R 22/065; G01R 27/2688

(57) ABSTRACT

An apparatus for electric power data collection and analysis includes a body comprising; at least one transducer configured to measure an electrical parameter of a monitored element; a data collection unit configured to collect data that comprises at least the electrical parameter measured by the at least one transducer; and a data analyzer configured to receive periodic data blocks from the data collection unit that comprises the data collected by the data collection unit. The electrical parameter includes at least one of the following: voltage, current, and/or power; and the elongated body is elongated to fit inside a space of an enclosure.

### CROSS-REFERENCE TO RELATED APPLICATIONS

This application claims the benefit from U.S. Provisional Application No. 63/557,324 filed on Feb. 23, 2024, which is hereby incorporated by reference in its entirety for all purposes as if fully set forth herein.

### FIELD OF THE DISCLOSURE

The disclosure relates to an electric power data collection device. The disclosure further relates to process of implementing an electric power data collection device. The disclosure further relates to a cloud-based analytics system. The disclosure also relates to a process of implementing a cloud-based analytics system.

### BACKGROUND OF THE DISCLOSURE

Power Quality (PQ) recorders are essential tools for electric utilities to diagnose and track voltage quality and electrical problems within their own network and for their customers. Often measurements must be made at the Point of Connection (POC), or at points downstream inside the customer facility to gather data at electrically relevant locations. In many cases the only practical monitoring point is inside a small existing enclosure such as a revenue meter base, a capacitor controller, etc. which contains the necessary voltage and current signals, but also is already filled with wiring and electrical apparatus.

In addition, conventional PQ monitors are large, bulky, and often awkwardly shaped due the special requirements they must meet. These include the ability to receive power from the voltage under measurement, implement very wide voltage input ranges, and implement large isolation barriers to meet safety specifications in Category III locations, Category IV locations, and/or the like. The conventional rectangular shape, large connectors, and standard cabling make it difficult or impossible for users to install portable PQ monitors in small existing cabinets used for revenue meters or other gear. This problem is exacerbated in areas where many channels must be measured, for example underground vaults with 12 or even 18 current-carrying conductors.

Conventional PQ monitors use a separate connector for local wired communications (e.g. USB); this adds to the PQ monitor size even if it's not in use. Additionally, these PQ monitors also locate input connectors along the top or other edge of the device and extend perpendicularly from the PQ monitor.

The disclosed device solves these problems with a novel mechanical and electrical design, allowing a PQ monitor to be placed in almost any location, while maintaining user safety. This disclosure combines the communications connector with a CT (current transformer) input connector, since typically wired communication is not used during the recording. Combining these facilitates maintaining the smallest cross section possible for the PQ monitor.

The PQ monitor maybe implement it with a cylindrical shape. Moreover, these logical shape is also ideal for placing the PQ monitor along a cabinet or enclosure edge, often the only space available. The lack of connectors or features that extend perpendicularly from the cylinder maintains the small cross-sectional area and maximizes the placement opportunities in a cabinet. Placing the voltage and CT connectors on the two cylinder ends maintains the smallest cross section, but at the expense of a longer device (small radius but longer height). This tradeoff is optimal in the typical PQ monitor location, where the device is placed inside a rectangular enclosure along an edge. These enclosures typically have plenty of length available, but need a device with at least one, if not two small dimensions.

This disclosure combines the communications connector with the CT input connector, since typically wired communication is not used during the recording. Combining these facilitates maintaining the smallest cross section possible for the PQ monitor.

### SUMMARY OF THE DISCLOSURE

The foregoing needs are met, to a great extent, by the disclosure, wherein an apparatus including an electric power data collection device (e.g., a power quality (PQ) monitor) and/or a method for an electric power data collection device is provided.

In one aspect, an apparatus includes at least one transducer configured to measure an electrical parameter of a monitored element. The apparatus in addition includes a data collection unit configured to collect data that comprises at least the electrical parameter measured by the at least one transducer. The apparatus moreover includes a data analyzer configured to receive periodic data blocks from the data collection unit that comprises the data collected by the data collection unit. The apparatus also includes an elongated body containing the at least one transducer, the data collection unit, the a data analyzer. The apparatus further includes where the electrical parameter comprises at least one of the following: voltage, current, and/or power. The apparatus in addition includes where the elongated body is configured to fit inside a space of an enclosure.

In one aspect, an apparatus includes at least one transducer configured to measure an electrical parameter of a monitored element. The apparatus in addition includes a data collection unit configured to collect data that comprises at least the electrical parameter measured by the at least one transducer. The apparatus moreover includes a data analyzer configured to receive periodic data blocks from the data collection unit that comprises the data collected by the data collection unit. The apparatus also includes an elongated body containing the at least one transducer, the data collection unit, the a data analyzer. The apparatus further includes where the electrical parameter comprises at least one of the following: voltage, current, and/or power. The apparatus in addition includes where the elongated body comprises a first dimension along a lateral axis and the elongated body comprises a second dimension along a longitudinal axis. The apparatus moreover includes where the second dimension is greater than the first dimension.

One aspect of the disclosure may include electrical and mechanical design elements that create a minimally sized monitor for installation in existing meter bases, electrical cabinets, and enclosures that already contain other equipment.

Another aspect of the disclosure may maximize the space where it is installed for power quality monitoring while maintaining full user safety and performance. This is useful when placing an electric power data collection device in an existing enclosure that is already filled with electrical apparatuses. The enclosure may be rectangular and may have empty areas along the edge(s) of the enclosure. The electric power data collection device may preferably be placed along the enclosure edge.

Additionally, the electric power data collection device may meet certain performance and safety standards. For example, the disclosed device may use the UL 61010 standard. This standard requires minimum creepage and clearance distances, along with isolation voltage requirements for different measurement categories. These categories relate to expected or possible levels of voltage transients and available fault energy.

A Category I node may be a regulated DC voltage such as from a USB power adapter. A Category II node may be a 120 VAC from a receptacle. However, there is typically no external power source available at utility measurement points. Thus, the disclosed device advantageously may require power by the measurement voltage, which is usually a Category III or IV node. Category III or IV nodes may be utility measurement points, where the minimum distance and isolation requirements are highest.

For a Category III node, the measurement voltage may be 600 V; for a Category IV node, the measurement voltage may be 300 V. The minimum distance may be 0.217 inches between voltage inputs. Implementing a safety standard as such may help to ensure user safety during operation. Thus, the power supply and the measurement input circuitry of the disclosed device may preferably meet the UL 61010 requirements.

In another aspect of the disclosed device, a circular voltage input connector may be used to achieve a small cross section while allowing spacing for polyphase inputs. By ensuring a small diameter for the cross section, this aspect of the disclosed device advantageously provides for small spacing and increased safety.

In one aspect of the disclosed device, the voltage input of the electric power data collection device is at one end, while a current transformer (CT) input is at another end of the electric power data collection device. The electric power data collection device may preferably be elongated and/or a cylinder with a circular cross section. Accordingly, the electric power data collection device may be placed along an edge of a cabinet or enclosure. The ends of the voltage input and the CT input may thereby facilitate placement along the edge of the cabinet or enclosure.

In another aspect of the disclosed device, the electric power data collection device may have a common input and 3 voltage inputs. In another aspect, the electric power data collection device may have a common input and 4 voltage inputs. Preferably, the voltage input, the CT input, and/or the common input extend in the same direction as the length of the electric power data collection device and do not extend perpendicularly from the electric power data collection device.

In another aspect of the disclosed device, a communication connector may be combined with the CT input connector. Such a communication connector may be for local wired communications including USB and/or the like. The communication connector may be in use while the CT input connector is not in use. This aspect may help to reduce the overall size of the electric power data collection device.

In another aspect of the disclosed device, the electric power data collection device may allow for wireless communication including Wi-Fi, Bluetooth, low energy Bluetooth (BLE), and/or the like. The electric power data collection device may be connected to a smart phone, tablet, a Wi-Fi network and/or the like to allow remote access, or access for a technician on-site.

In another aspect, the wireless communication may allow for communication with one or more sensors. These sensors may be environmental sensors which may measure ambient temperature, air pressure, humidity, solar flux, vibration, door closure, and/or air quality. Such sensors may preferably communicate with the electric power data collection device using a BLE interface. These sensors may alternatively be medium voltage sensors. Such sensors may stream raw waveform data with at least one electric power data collection device to create a virtual 3 phase MV power quality monitor, in parallel with its own measurement system.

Another aspect of the disclosed device relates to a system where at least one electric power data collection device may communicate with another electric power data collection device. This communication may involve wired or wireless communications described herein. This aspect may increase the ability for the electric power data collection device(s) to review situations where there are more inputs than one electric power data collection device can record.

In another aspect of the disclosed device, the system may have 4 to 6 electric power data collection devices, each measuring three current inputs. The electric power data collection devices may be placed in a network distribution grid in an underground vault with 3 voltage inputs. The system may synchronize the sampling and recording of the electric power data collection devices using known sync protocols such as NTP, IEEE 1588, and/or the like. The synchronization may occur at A/D sample or 60 Hz cycle level. The system may analyze the electric power data collection devices together with overlaid waveforms or may analyze the individual electric power data collection devices as one large virtual electric power data collection device.

In one aspect of the disclosed device, the electric power data collection device may operate as a standalone monitor, or in conjunction with a wireless interface such as cloud-based software. The electric power data collection device may include voltage and current transducers, signal conditioning, and an A/D sampling system which allows all PQ metrics to be computed in real time.

In another aspect of the disclosed device, the sampling rate of the A/D sampling system may be 256 samples per 60 Hz cycle (15,360 Hz) per signal or 65 microsecond sample length. Further, raw waveform samples may be fed into a digital signal processor (DSP). The DSP may compute PQ metrics such as RMS voltage, RMS current, real, reactive and apparent power, power factor, displacement power factor, phase angle, harmonic magnitudes and phases, IFL, Pst, and Plt flicker, symmetrical components, and/or the like on a cycle-by-cycle basis or other time period. Preferably, the sampling may be synchronized to the line frequency through software phased locked loop (PLL) algorithms.

In one aspect of the disclosed device, the PQ metrics may be aggregated into 1 second averages, maximums, and/or minimums. Additionally, programmable triggers may cause the cycle readings or raw waveform data to be stored as a waveform capture record. The PQ metrics may also be aggregated into longer term averages, daily profiles, histograms, flicker records, or significant changes, and/or the like. The aggregation sizes for triggered waveforms, transients, and other triggered PQ events may be different and user adjustable. The data may be timestamped from an internal real time clock (RTC) of the electric power data collection device. This RTC may be battery-backed or powered via supercapacitor during an outage.

In another aspect of the disclosed device, the electric power data collection device may record and store the triggered waveforms, transients, data aggregations, histograms, daily profiles, and/or the like into internal non-volatile memory. Additionally, the electric power data collection device may also record and store the triggered waveforms, transients, data aggregations, histograms, daily profiles, and/or the like into a cloud system via a wireless connection such as Wi-Fi. In case of temporary loss in wireless connection, the internal non-volatile memory may allow for later transmission to the cloud system when the connection is restored. This set up may also allow for data download by a downloading device such as a PC, tablet, or smartphone in stand-alone applications. This data may be analyzed directly on the downloading device, saved to a data file, or uploaded to the cloud system later. Once uploaded, the data may be available to cloud users as if it had been sent directly by the device.

In another aspect of the disclosed device, the electric power data collection device may also include the ability to stream data to a local device, such as a personal digital assistant (PDA), smart phone, tablet, PC, and/or the like. The local device may connect to the electric power data collection device using a wireless communication protocol, such as Bluetooth, Wi-Fi, and/or the like. The local device may operate as a master device with the electric power data collection device operating as a slave device. The local device may operate as a central device with the electric power data collection device operating as a peripheral device. The electric power data collection device may be a host of a network Access Point and the local device may join the network. Alternatively, a separate device may be the host of a network Access Point with the local device and electric power data collection device joining the network of the separate device.

The local device may also include an application to query and display the real-time waveforms, harmonics, vector diagrams, and/or the like from the electric power data collection device. The local device may download any recorded data from the electric power data collection device. The local device may also connect to the cloud system. The cloud system may present data to a user through the local device, with customizations for device-specific interaction such as swipe and other gestures, pinch to zoom, rotating screen, and/or the like.

In another aspect of the disclosed device, the electric power data collection device may include suitable voltage and current transducers for connecting to low voltage (600 V and below) power distribution networks. The electric power data collection device may include a DSP for computing real-time PQ measurements. A secondary processor such as a 32-bit ARM-based controller may collect data from the DSP, manage communications from all ports, handle data storage, and perform all other processing. The electric power data collection device may have communication ports including Bluetooth (Class 1, 2, and Low Energy), Wi-Fi (ad-hoc and Access Point mode), high speed USB, and BLE (for connection to other sensors). Further, the electric power data collection device may draw power from the voltage or current signals that it is measuring. In one aspect of the disclosed device, the electric power data collection device may use an AC power supply capable of powering the device over the full measurement range (e.g. 60-600 VAC) such as a rechargeable battery or super capacitor and/or the like which may allow for ride-thru power during a power outage. This ride-thru time may be long enough to cover the longest expected recloser cycling time such as 5 minutes.

In one aspect of the disclosed device, the electric power data collection device may operate as a standalone monitor, or in conjunction with a wireless interface such as cloud-based software. The electric power data collection device may include voltage and current transducers, signal conditioning, and an A/D sampling system which allows all PQ metrics to be computed in real time.

In another aspect of the disclosed device, the sampling rate of the A/D sampling system may be 256 samples per line cycle (1/256×60 Hz) or 65 microsecond sample length. Further, raw waveform samples may be fed into a digital signal processor (DSP). The DSP may compute PQ metrics such as RMS voltage, RMS current, real, reactive and apparent power, power factor, displacement power factor, phase angle, harmonic magnitudes and phases, IFL, Pst, and Plt flicker, symmetrical components, and/or the like on a cycle-by-cycle basis or other time period. Preferably, the sampling may be synchronized to the line frequency through software phased locked loop (PLL) algorithms.

In one aspect of the disclosed device, the PQ metrics may be aggregated into 1 second averages, maximums, and/or minimums. Additionally, programmable triggers may cause the cycle readings or raw waveform data to be stored as a waveform capture record. The PQ metrics may also be aggregated into longer term averages, daily profiles, histograms, flicker records, or significant changes, and/or the like. The aggregation sizes for triggered waveforms, transients, and other triggered PQ events may be different and user adjustable. The data may be timestamped from an internal real time clock (RTC) of the electric power data collection device. This RTC may be battery-backed or powered via supercapacitor during an outage.

In another aspect of the disclosed device, the electric power data collection device may record and store the triggered waveforms, transients, data aggregations, histograms, daily profiles, and/or the like into internal non-volatile memory. Additionally, the electric power data collection device may also record and store the triggered waveforms, transients, data aggregations, histograms, daily profiles, and/or the like into a cloud system via a wireless connection such as Wi-Fi. In case of temporary loss in wireless connection, the internal non-volatile memory may allow for later transmission to the cloud system when the connection is restored. This set up may also allow for data download by a downloading device such as a PC, tablet, or smartphone in stand-alone applications. This data may be analyzed directly on the downloading device, saved to a data file, or uploaded to the cloud system later. Once uploaded, the data may be available to cloud users as if it had been sent directly by the device.

In another aspect of the disclosed device, the electric power data collection device may also include the ability to stream data to a local device, such as a personal digital assistant (PDA), smart phone, tablet, PC, and/or the like. The local device may connect to the electric power data collection device using a wireless communication protocol, such as Bluetooth, Wi-Fi, and/or the like. The local device may operate as a master device with the electric power data collection device operating as a slave device. The local device may operate as a central device with the electric power data collection device operating as a peripheral device. The electric power data collection device may be a host of a network Access Point and the local device may join the network. Alternatively, a separate device may be the host of a network Access Point with the local device and electric power data collection device joining the network of the separate device.

The local device may also include an application to query and display the real-time waveforms, harmonics, vector diagrams, and/or the like from the electric power data collection device. The local device may download any recorded data from the electric power data collection device. The local device may also connect to the cloud system. The cloud system may present data to a user through the local device, with customizations for device-specific interaction such as swipe and other gestures, pinch to zoom, rotating screen, and/or the like.

In another aspect of the disclosed device, the electric power data collection device may include suitable voltage and current transducers for connecting to low voltage (600 V and below) power distribution networks. The electric power data collection device may include a DSP for computing real-time PQ measurements. A secondary processor such as a 32-bit ARM-based controller may collect data from the DSP, manage communications from all ports, handle data storage, and perform all other processing. The electric power data collection device may have communication ports including Bluetooth (Class 1, 2, and Low Energy), Wi-Fi (ad-hoc and Access Point mode), high speed USB, and BLE (for connection to other sensors). Further, the electric power data collection device may draw power from the voltage or current signals that it is measuring. In one aspect of the disclosed device, the electric power data collection device may use an AC power supply capable of powering the device over the full measurement range (e.g. 60-600 VAC) such as a rechargeable battery or super capacitor and/or the like which may allow for ride-thru power during a power outage. This ride-thru time may be long enough to cover the longest expected recloser cycling time such as 5 minutes.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a perspective side view of an electric power data collection device according to aspects of the disclosure.

FIG. 2 illustrates a perspective side view of another electric power data collection device according to aspects of the disclosure.

FIG. 3 illustrates a side view of another electric power data collection device according to aspects of the disclosure.

FIG. 4 illustrates a perspective side view of the electric power data collection device of FIG. 3.

FIG. 5 illustrates a cross-sectional bottom view along lines V-V of the electric power data collection device of FIG. 3.

FIG. 6 illustrates an electric power data collection device installed in an enclosure according to aspects of the disclosure.

FIG. 7 illustrates an installation of electric power data collection devices according to aspects of the disclosure.

FIG. 8 illustrates a system according to aspects of the disclosure.

FIG. 9 illustrates a data collection unit according to aspects of the disclosure.

FIG. 10 illustrates a data analyzer according to aspects of the disclosure.

FIG. 11 illustrates an exemplary implementation of a cloud-based server system according to aspects of the disclosure.

FIG. 12 illustrates a process for electric power data collection and analysis according to aspects of the disclosure.

### DETAILED DESCRIPTION

The disclosure will now be described with reference to the drawing figures, in which like reference numerals refer to like parts throughout. Aspects of the disclosure advantageously provide an electric power data collection device, a process of implementing an electric power data collection device, an electric power data collection and analysis device, and/or a process of implementing an electric power data collection and analysis device.

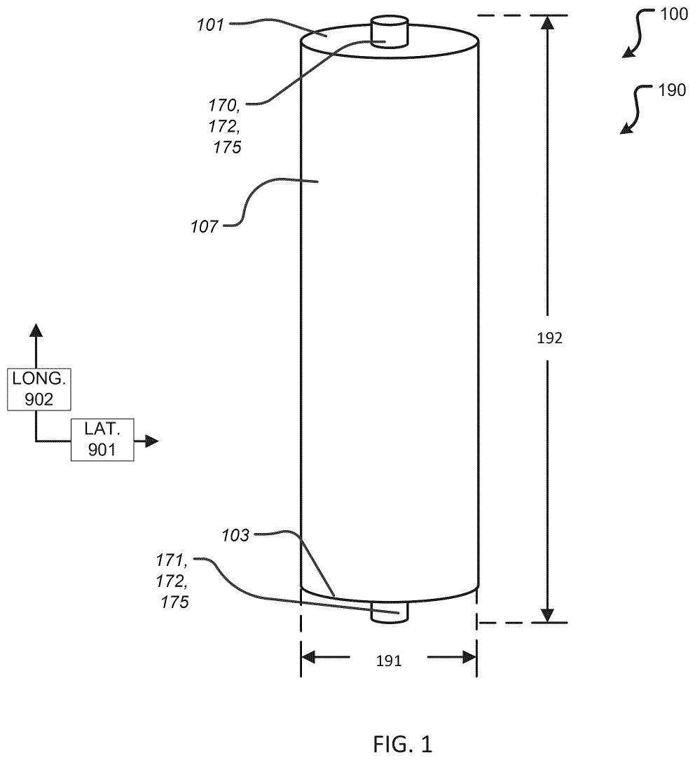

FIG. 1 illustrates a perspective side view of an electric power data collection device according to aspects of the disclosure.

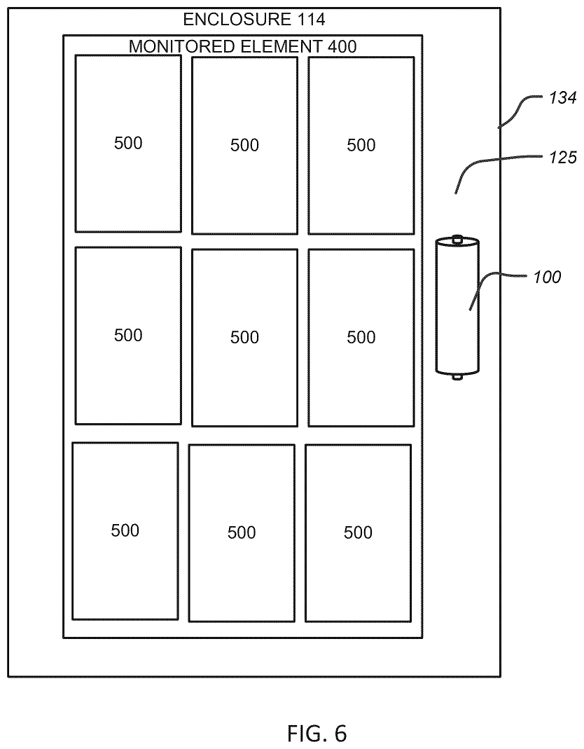

In particular, FIG. 1 illustrates an electric power data collection device 100 configured to be implemented as a PQ monitor, a power quality monitor, and/or the like. As illustrated in FIG. 1, the electric power data collection device 100 may have a cylindrical form factor. This form factor allows the electric power data collection device 100 to have a circular cross section with an elongated body 190 to fit within a space 125 of an enclosure 114 as illustrated in FIG. 6. However, the electric power data collection device 100 may have any other cross sectional shapes and/or form factors that may also include an elongated body 190.

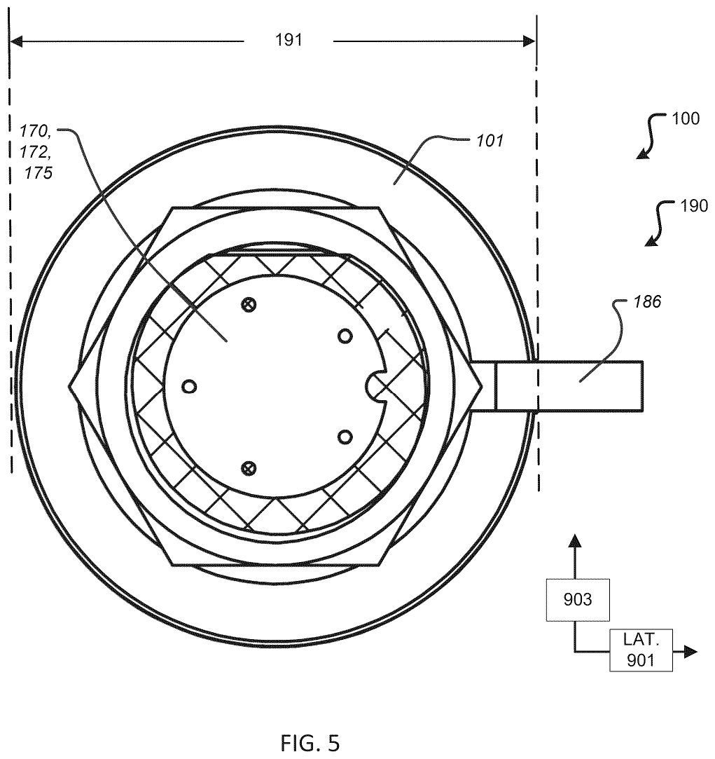

In this regard, the electric power data collection device 100 may include a top end surface 101 and a bottom end surface 103. In aspects, the top end surface 101 and the bottom end surface 103 may be arranged on opposing ends of the electric power data collection device 100 along a longitudinal axis 902. Further, the top end surface 101 and the bottom end surface 103 may extend generally along a lateral axis 901 and/or an orthogonal axis 903 as illustrated in FIG. 5.

Further, the electric power data collection device 100 may include at least one side surface 107 extending between the top end surface 101 and the bottom end surface 103. Further, the at least one side surface 107 may extend generally along the longitudinal axis 902.

In aspects, the top end surface 101, the bottom end surface 103, and the at least one side surface 107 may form a housing and/or the elongated body 190 that encapsulates the components of the electric power data collection device 100. In aspects, the housing of the electric power data collection device 100 may may meet certain performance and safety standards. In aspects, the housing of the electric power data collection device 100 may meet the UL 61010 standard. In aspects, the housing of the electric power data collection device 100 may implement minimum creepage and clearance distances, along with isolation voltage requirements for different measurement categories. In aspects, the housing of the electric power data collection device 100 may form a hermetically sealed construction to protect the components of the electric power data collection device 100 from water, shock, and/or the like. In aspects, the housing of the electric power data collection device 100 may include potting materials, waterproofing materials, insulating materials, dielectric materials, water resistant materials, and/or the like.

The disclosure and figures make reference to certain axes that include the lateral axis 901, the longitudinal axis 902, and the orthogonal axis 903. In aspects, these axes are meant to describe the structural arrangement, spatial arrangement, and/or the like of various components of the electric power data collection device 100 and/or features of various components of the electric power data collection device 100. In aspects, the lateral axis 901 extends along a direction perpendicular to the longitudinal axis 902 and the orthogonal axis 903; the longitudinal axis 902 extends along a direction perpendicular to the lateral axis 901 and the orthogonal axis 903; and the orthogonal axis 903 extends along a direction perpendicular to the lateral axis 901 and the longitudinal axis 902. In aspects, utilization of the lateral axis 901 and the longitudinal axis 902 are not meant to denote that one axis of the electric power data collection device 100 is longer or shorter than another axis of the electric power data collection device 100.

In aspects, the electric power data collection device 100 may have connectorized inputs for one or more voltage signals 170, a CT connector 175 for one or more current inputs 171, and/or the like. For example, each of the electric power data collection device 100 may have connectorized inputs for three voltage inputs, and a CT connector 175 for three current inputs 171.

In another aspect of the electric power data collection device 100, each of the electric power data collection device 100 may comply with the UL 61010 standard. A typical voltage input level of the electric power data collection device 100 may be 300 V RMS (i.e., a Category IV node) or 600 V RMS (i.e., a Category III node), from monitoring PTs (Potential Transformers) outside the electric power data collection device 100.

In another aspect of the electric power data collection device 100, the one or more connectorized inputs for voltage signals 170 and/or the CT connector 175 for one or more current inputs 171 may have a circular cross section. The one or more connectorized inputs for voltage signals 170 and/or the CT connector 175 for one or more current inputs 171 may also extend in the same direction as the length of the electric power data collection device 100 and do not extend perpendicularly from the electric power data collection device 100. This feature may be used to achieve a small cross section while allowing spacing for polyphase inputs in the enclosure 114 of the installation 115. The distance between the one or more connectorized inputs for voltage signals 170 and/or the CT connector 175 for one or more current inputs 171 may be 0.217 inches.

In another aspect of the electric power data collection device 100, the one or more connectorized inputs for voltage signals 170 is at the top end surface 101 of the electric power data collection device 100 and the one or more CT connector 175 for one or more current inputs 171 is at the bottom end surface 103 of the electric power data collection device 100. In another aspect, a communication connector 172 may be combined with the CT connector 175. Such a communication connector 172 may be for local wired communications including USB and/or the like. The communication connector may be in use while the CT input connector is not in use.

In some embodiments or use cases, the electric power data collection device 100 may be configured to provide a differing number of voltage and current channels. For example, in situations with multiple circuits that share a common voltage bus, a single three phase voltage input may suffice for all circuits, but each circuit has its own three phase current signals. The electric power data collection device 100 may be configurable to enable or disable voltage and current channels as needed to avoid storing redundant data. If only one voltage circuit is needed, individual data collection units 102 may synchronize to that common voltage input, without need to record redundant voltage inputs. Alternatively, the data collection unit 102 may synchronize to their own current inputs, to an external timing pulse (e.g. from GPS, NTP, IRIG-B, or IEEE 1588 as described above), and/or the like. In one aspect, the synchronization may occur at an A/D sample or 60 Hz cycle level.

Another possible embodiment may be a virtual concentrator implementation of the data analyzer 150, with data collection devices streaming data through a network, a cellular data connection, a communication channel as defined herein, and/or the like to a cloud-based analytics system 300, a cloud-based receiver, and/or the like. This virtual concentrator implementation of the data analyzer 150 may be a virtual machine on a hosted system, a scalable system, such as Amazon Web Services (AWS), and/or the like.

Additionally, the electric power data collection device 100 may implement a CT connector 175. In aspects, the CT connector 175 may be arranged on the top end surface 101. In aspects, the CT connector 175 may be arranged on the bottom end surface 103. In aspects, the CT connector 175 may be arranged on the top end surface 101 and may be arranged on the bottom end surface 103.

In aspects, the electric power data collection device 100 and/or the elongated body 190 may have a first dimension 191 along the lateral axis 901 that may be characterized as a width, a diameter, and/or the like. In aspects, the components of the electric power data collection device 100 and/or the elongated body 190 may include the top end surface 101, the bottom end surface 103, and the at least one side surface 107 that may be arranged, structured, and/or confined within the first dimension 191.

In aspects, the electric power data collection device 100 and/or the elongated body 190 may have a second dimension 192 along the longitudinal axis 902 that may be characterized as a length, a height, and/or the like. In aspects, the components of the electric power data collection device 100 and/or the elongated body 190 may include the top end surface 101, the bottom end surface 103, and the at least one side surface 107 that may be arranged, structured, and/or confined within the second dimension 192.

In aspects, the top end surface 101 may have a dimension consistent with the first dimension 191. In aspects, the bottom end surface 103 may have a dimension consistent with the first dimension 191. In aspects, the top end surface 101 and the bottom end surface 103 may have the same dimension. In aspects, the top end surface 101 and the bottom end surface 103 may have a dimension consistent with the first dimension 191.

In aspects, the second dimension 192 may include a total length of the electric power data collection device 100 including the at least one side surface 107, the one or more connectorized inputs for voltage signals 170, the communication connector 172, the CT connector 175, and any ports, connectors, intervening structure, and/or the like.

In aspects, the second dimension 192 may be greater than the first dimension 191. In aspects, the second dimension 192 may be 1.5-5 times greater than the first dimension 191. In aspects, the second dimension 192 may be 1.5, 2.0, 2.5, 3.0, 3.5, 4.0, 4.5, 5.0, or more times greater than the first dimension 191. In aspects, the second dimension 192 may be 1.5-2.0, 2.0-2.5, 2.5-3.0, 3.0-3.5, 3.5-4.0, 4.0-4.5, or 4.5-5.0 times greater than the first dimension 191.

In aspects, the first dimension 191 may be 1-4 inches, 1-2 inches, 1.5-2 inches, 1.6-1.7 inches, or 1-3 inches. In aspects, the first dimension 191 may be approximately 1.662 inches.

In aspects, the second dimension 192 may be 3-7 inches, 3-4 inches, 4-5 inches, 4.5-5 inches, or 5-6 inches. In aspects, the second dimension 192 may be approximately 4.76 inches.

In aspects, the electric power data collection device 100 may be constructed such that the first dimension 191 and the second dimension 192 configure the electric power data collection device 100 as the elongated body 190 to fit within a space 125 of an enclosure 114 as illustrated in FIG. 6. Thus, this slender cylindrical form factor of the electric power data collection device 100 provides for a beneficial arrangement in enclosures with limited free space, which is typically narrow.

The aspects of the electric power data collection device 100 illustrated in FIG. 1 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 1.

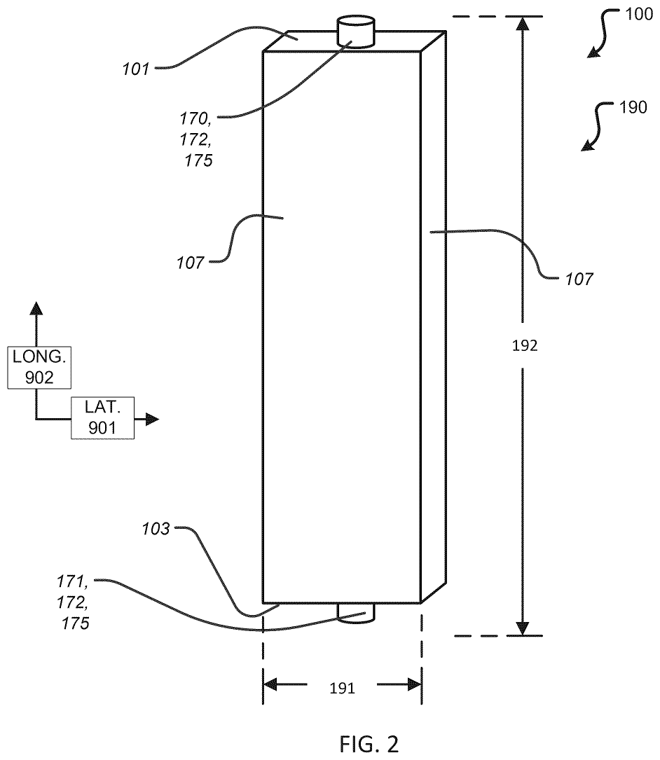

FIG. 2 illustrates a perspective side view of another electric power data collection device according to aspects of the disclosure.

FIG. 2 illustrates another electric power data collection device 100 configured to be implemented as a PQ monitor, a power quality monitor, and/or the like. The electric power data collection device 100 may have a rectangular prism form factor. In this regard, the electric power data collection device 100 may include the top end surface 101, the bottom end surface 103, and the at least one side surface 107. As illustrated in FIG. 2, the electric power data collection device 100 includes a plurality of the at least one side surface 107.

In aspects, the electric power data collection device 100 and/or the elongated body 190 may have a first dimension 191 along the lateral axis 901 that may be characterized as a width, a diameter, and/or the like. In aspects, the components of the electric power data collection device 100 and/or the elongated body 190 may include the top end surface 101, the bottom end surface 103, and the at least one side surface 107 that may be arranged, structured, and/or confined within the first dimension 191.

In aspects, the components of the electric power data collection device 100 and/or the elongated body 190 may include the top end surface 101, the bottom end surface 103, and the at least one side surface 107 that may be arranged, structured, and/or confined within the second dimension 192.

In aspects, the second dimension 192 may include a total length of the electric power data collection device 100 and/or the elongated body 190 may include the at least one side surface 107, the one or more connectorized inputs for voltage signals 170, the communication connector 172, the CT connector 175, and any ports, connectors, intervening structure, and/or the like.

In aspects, the electric power data collection device 100 may be constructed such that the first dimension 191 and the second dimension 192 configure the electric power data collection device 100 as the elongated body 190 to fit within a space 125 of an enclosure 114 as illustrated in FIG. 6. Thus, this slender form factor of the electric power data collection device 100 provides for a beneficial arrangement in enclosures with limited free space, which is typically narrow.

The aspects of the electric power data collection device 100 illustrated in FIG. 2 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 2.

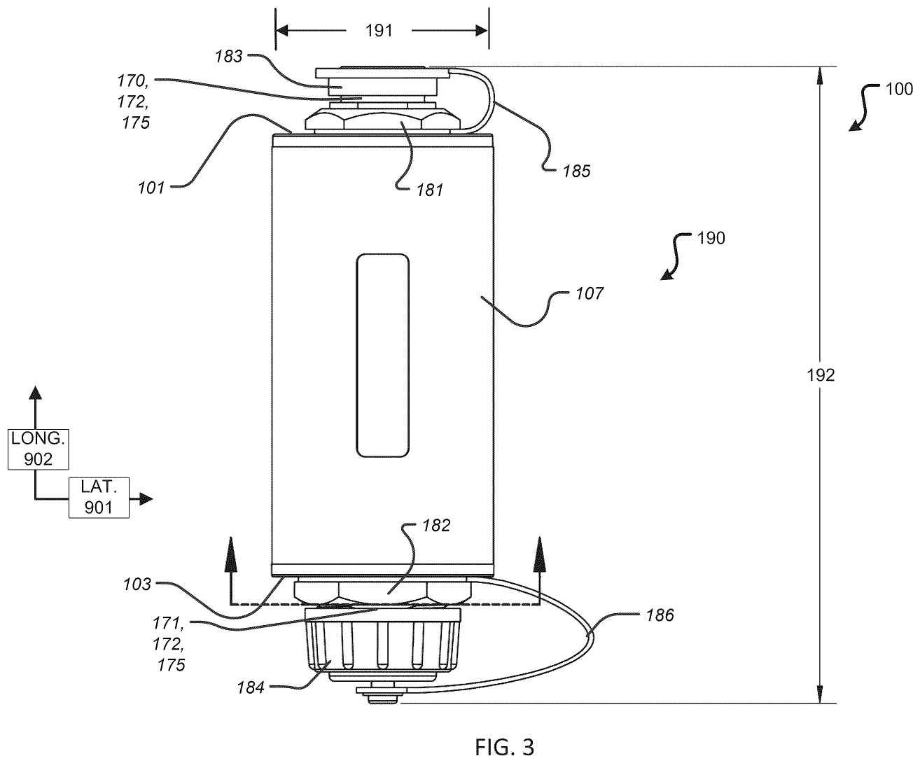

FIG. 3 illustrates a side view of another electric power data collection device according to aspects of the disclosure.

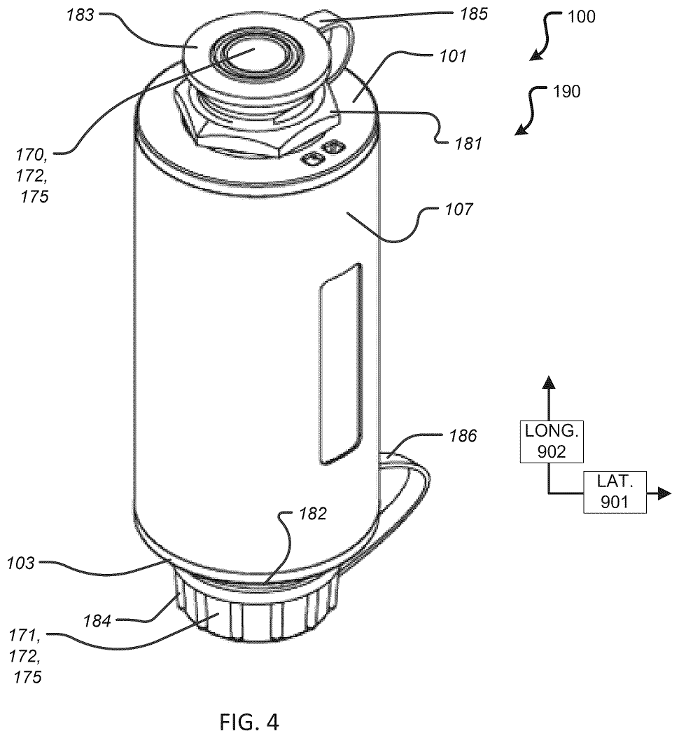

FIG. 4 illustrates a perspective side view of the electric power data collection device of FIG. 3.

FIG. 5 illustrates a cross-sectional bottom view along lines V-V of the electric power data collection device of FIG. 3.

In particular, FIG. 3, FIG. 4, and FIG. 5 illustrate another aspect of the electric power data collection device 100 configured to be implemented as a PQ monitor, a power quality monitor, and/or the like. In this regard, the electric power data collection device 100 may have a slender cylindrical form factor.

In aspects, the electric power data collection device 100 may include the top end surface 101, the bottom end surface 103, and the at least one side surface 107. In aspects, the at least one side surface 107 that may be configured as a cylindrical surface that extends between the top end surface 101 and the bottom end surface 103.

In aspects, the one or more connectorized inputs for voltage signals 170, the communication connector 172, and/or the CT connector 175 may be arranged on the top end surface 101. In aspects, the one or more connectorized inputs for voltage signals 170, the communication connector 172, and/or the CT connector 175 may be arranged in a top connector portion 181.

In aspects, the top connector portion 181 may extend from the top end surface 101 along the longitudinal axis 902. In aspects, the top connector portion 181 may include a cover 183, a lanyard 185, and/or the like.

In aspects, the cover 183 may be configured to cover and protect the one or more connectorized inputs for voltage signals 170, the communication connector 172, and/or the CT connector 175. In aspects, the cover 183 may provide a waterproof and/or watertight configuration.

In aspects, the lanyard 185 may allow removal of the cover 183. Further, the lanyard 185 may configured to prevent the cover 183 from being disassociated with the electric power data collection device 100.

In aspects, the one or more connectorized inputs for voltage signals 170, the communication connector 172, and/or the CT connector 175 may be arranged on the bottom end surface 103. In aspects, the one or more connectorized inputs for voltage signals 170, the communication connector 172, and/or the CT connector 175 may be arranged in a bottom connector portion 182.

In aspects, the bottom connector portion 182 may extend from the bottom end surface 103 along the longitudinal axis 902. In aspects, the bottom connector portion 182 may include a cover 184, a lanyard 186, and/or the like.

In aspects, the cover 184 may be configured to cover and protect the one or more connectorized inputs for voltage signals 170, the communication connector 172, and/or the CT connector 175. In aspects, the cover 184 may provide a waterproof and/or watertight configuration.

In aspects, the lanyard 186 may allow removal of the cover 184. Further, the lanyard 186 may configured to prevent the cover 184 from being disassociated with the electric power data collection device 100.

In aspects, the electric power data collection device 100 and/or the elongated body 190 may have a first dimension 191 along the lateral axis 901 that may be characterized as a width, a diameter, and/or the like. In aspects, the components of the electric power data collection device 100 and/or the elongated body 190 may include the top end surface 101, the bottom end surface 103, and the at least one side surface 107 that may be arranged, structured, and/or confined within the first dimension 191.

In aspects, the components of the electric power data collection device 100 and/or the elongated body 190 may include the top end surface 101, the bottom end surface 103, the top connector portion 181, the bottom connector portion 182, and the at least one side surface 107 may be arranged, structured, and/or confined within the second dimension 192.

In aspects, the second dimension 192 may include a total length of the electric power data collection device 100 and/or the elongated body 190 may include the at least one side surface 107, the one or more connectorized inputs for voltage signals 170, the communication connector 172, the CT connector 175, the top connector portion 181, the bottom connector portion 182, and any ports, connectors, intervening structure, and/or the like.

In aspects, the electric power data collection device 100 may be constructed such that the first dimension 191 and the second dimension 192 configure the electric power data collection device 100 as an elongated body 190 to fit within a space 125 of an enclosure 114 as illustrated in FIG. 6. Thus, this slender cylindrical form factor of the electric power data collection device 100 provides for a beneficial arrangement in enclosures with limited free space, which is typically narrow.

Other elongated body form factors of the electric power data collection device 100 may be envisioned such as triangular, hexagonal, octagonal prisms and/or the like. The form factor of the electric power data collection device 100 allows the elongated body 190 to fit within the space 125 of the enclosure 114.

The aspects of the electric power data collection device 100 illustrated in FIGS. 3-5 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIGS. 3-5.

FIG. 6 illustrates further aspects of a data collection unit according to aspects of the disclosure.

In aspects, electric power data collection device 100 may be arranged in an enclosure 114. In aspects, the enclosure 114 may be a rack enclosure. In aspects, the enclosure 114 may include one or more fastening systems, structural support systems, rails, cooling systems, and/or the like. The enclosure 114 may also include one or more electric components 500 associated with a monitored element 400 including one or more circuits, one or more machines, one or more components, and/or the like. The enclosure 114 may be configured to have a space 125 along an edge 134 of the enclosure 114 left over after installing all other electronic components. Each of the electric power data collection device 100 may be configured to fit inside the space 125 of the enclosure 114.

The aspects of the electric power data collection device 100 illustrated in FIG. 6 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 6.

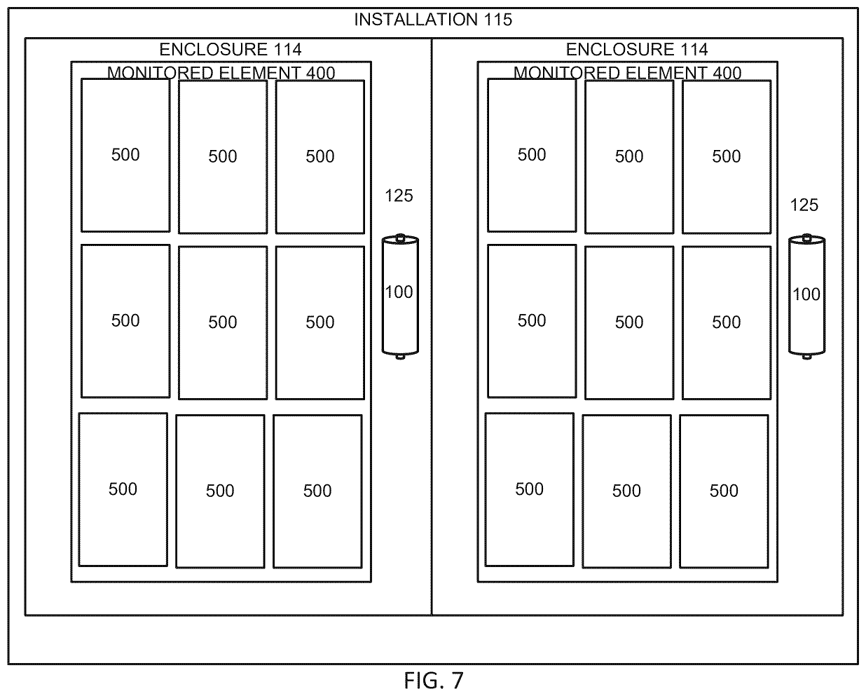

FIG. 7 illustrates an installation of electric power data collection devices according to aspects of the disclosure.

With respect to FIG. 7, the electric power data collection device 100, may be configured as an installation 115, which may include one or more enclosures 114. In aspects, the installation 115 may include the electric power data collection device 100, the data collection units 102, the data analyzers 150, and/or the like in a rack or series of racks as the one or more enclosures 114, such as a standard 19 inch rack. In aspects, the installation 115 may hold four implementations of the electric power data collection devices 100 or six implementations of the electric power data collection devices 100.

In aspects where the installation 115 may have more than one electric power data collection devices 100, one electric power data collection device 100 of one enclosure 114 may communicate with another electric power data collection device 100 of the installation 115. This communication may involve wired or wireless communication channels.

Additionally, the installation 115 may include the voltage input connections and current input connections to a monitored element 400 to be monitored and applying power. In one aspect, the one or more enclosures 114 has a space 125 along an edge 134 of the enclosure 114, which is left over after installing all electronic components. Each of the electric power data collection device 100 may be configured to fit inside the space 125 of the enclosure 114.

The aspects of the electric power data collection device 100 illustrated in FIG. 7 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 7.

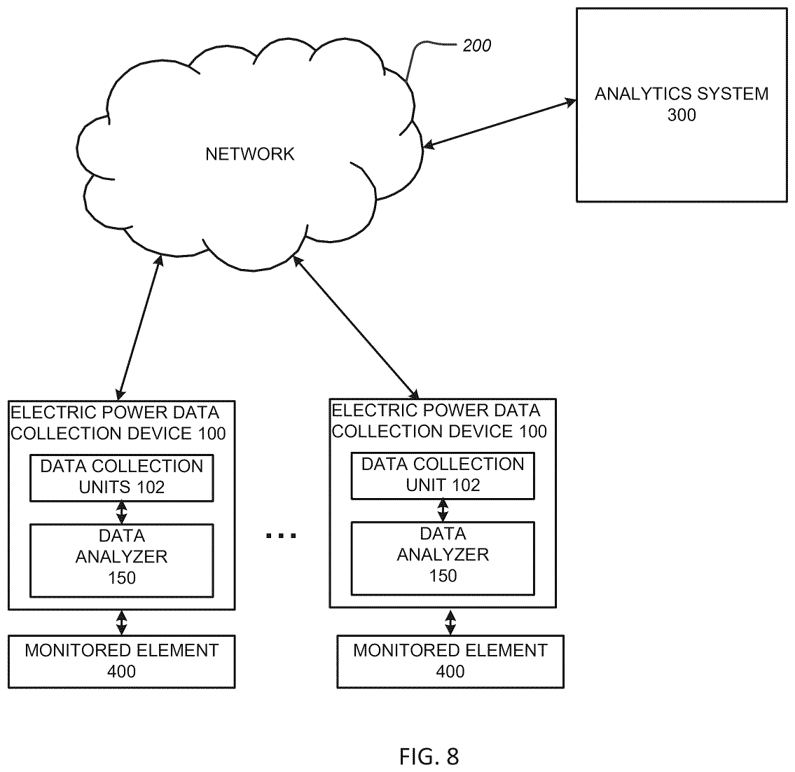

FIG. 8 illustrates a system according to aspects of the disclosure.

With reference to FIG. 8, the electric power data collection device 100 may be configured to collect and analyze power data for a monitored element 400. The monitored element 400 may be an electrical substation, a solar farm, a wind farm, a Distributed Energy Resource (DER), a portion of a utility transmission infrastructure, a portion of a utility generation infrastructure, one or more circuits, one or more machines, one or more components, and/or the like. The one or more electric power data collection device 100 may include two components. The first component may be implemented as a data collection unit 102. The second component may be implemented as a data analyzer 150.

In aspects, the data collection unit 102 may include at least one transducer configured to measure one or more electrical parameters associated with the monitored element 400 such as voltage, current, power, and/or the like. With reference to FIG. 2, the data collection unit 102 may include a voltage transducer 104, a current transducer 106, a sampling system 108 that may include an A/D (analog to digital) converter, and/or the like.

In aspects, the voltage transducer 104 may be configured to measure an electrical parameter such as a voltage associated with the monitored element 400. In this regard, the voltage transducer 104 may be configured with components, circuits, and/or the like for voltage measurement.

In aspects, the current transducer 106 may be configured to measure an electrical parameter such as a current associated with the monitored element 400. In this regard, the current transducer 106 may be configured with components, circuits, and/or the like for current measurement.

In aspects, the data collection unit 102 may include multiple implementations of the voltage transducer 104. In aspects, the data collection unit 102 may include multiple implementations of the current transducer 106. In aspects, the data collection unit 102 may include multiple implementations of the voltage transducer 104 and multiple implementations of the current transducer 106. In aspects, the data collection unit 102 may include one or more implementations of the voltage transducer 104 without any implementations of the current transducer 106. In aspects, the data collection unit 102 may include one or more implementations of the current transducer 106 without any implementations of the voltage transducer 104.

The aspects of the electric power data collection device 100 illustrated in FIG. 8 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 8.

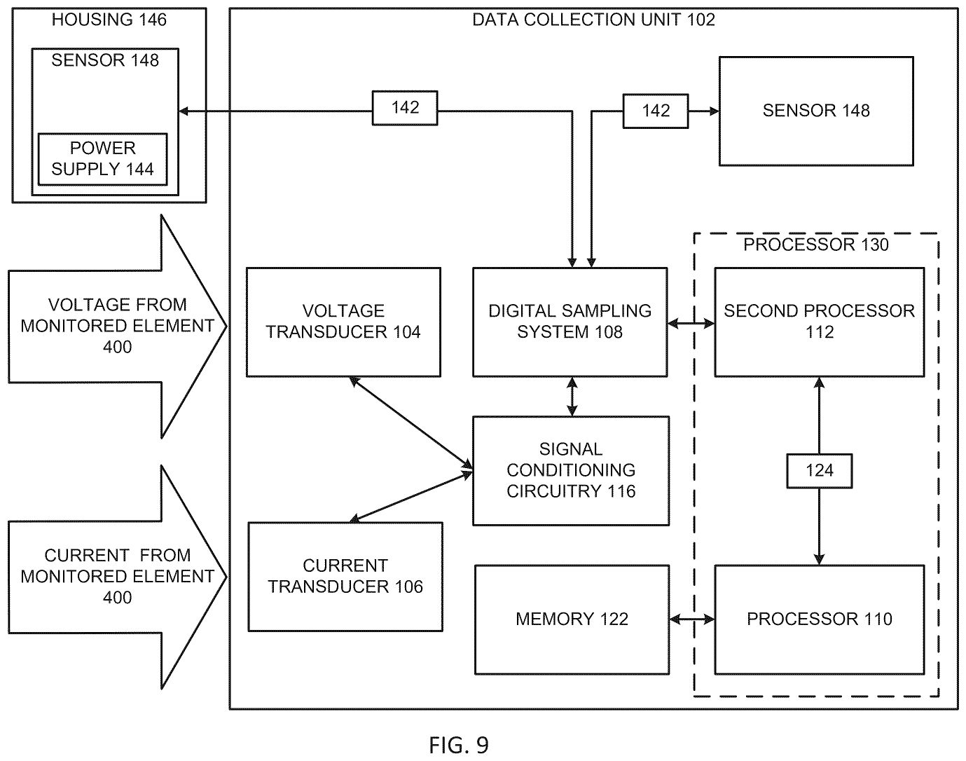

FIG. 9 illustrates a data collection unit according to aspects of the disclosure.

With further reference to FIG. 9, the data collection unit 102 may include at least one sensor 148 and/or may connect to at least one sensor 148. In aspects, the electric power data collection device 100, the data analyzer 150, and/or the like may include at least one sensor 148 and/or may connect to at least one sensor 148.

In aspects, the data collection unit 102 may be a dual-processor system that may implement the processor 110 and the second processor 112. In aspects, the processor 110 may be implemented as a primary ARM (Advanced RISC Machine) processor. In aspects, the processor 110 may be implemented as a primary ARM processor running embedded Linux.

In aspects, the second processor 112 may be implemented as a secondary DSP processor. In aspects, the second processor 112 may be implemented as a secondary DSP processor handling data sampling, pre-processing, and/or the like. The second processor 112 may be a 32-bit ARM-based controller and may collect data from the DSP, manage communications from all ports, handle data storage, and perform all other processing.

The electric power data collection device 100 may also include a high-speed A/D converter that may be implemented as part of the sampling system 108 and signal conditioning circuitry 116.

The data collection unit 102 of the electric power data collection device 100 may be configured for data sampling. In aspects, data collection unit 102 may be configured for data sampling at 256 samples per 60 Hz cycle (15,360 Hz) per signal or 65 microsecond sample length. Other sampling rates, such as lower sampling rates (as low as 64 samples per cycle) are possible in some configurations of the data collection unit 102. A higher sampling rate (such as 1 MHZ) may be used to allow characterization of high frequency powerline noise signals, fast risetime transients, other high frequency signals that may be useful in machine learning training, and/or the like.

The A/D that may be implemented as part of the sampling system 108 may have any desired resolution. In aspects, the A/D that may be implemented as part of the sampling system 108 may have a resolution of at least 14 or 16 bits.

In aspects, the A/D that may be implemented as part of the sampling system 108 may implement oversampling techniques. The oversampling techniques may be used to trade off resolution and sampling rate. In one aspect, sampling by the A/D may be performed at 250 kHz with a 14 bit resolution, and the DSP implementation of the second processor 112 may downsample to 15,360 Hz with increased resolution. The downsampling performed by the DSP implementation of the second processor 112 may also incorporate phase locking so that the downsampled waveform may be synchronous to a 60 Hz reference signal (e.g. voltage channel one), even if the high speed raw data at 250 KHz is not synchronous. This may be accomplished by the DSP implementation of the second processor 112 utilizing continuous fast Fourier transform (FFT) analysis of the reference signal, and tracking the 60 Hz phase information, then adjusting the downsampled rate accordingly.

The data collection unit 102 may be configured such that voltage inputs and current inputs may be sampled simultaneously. Alternatively, the data collection unit 102 may be configured such that voltage inputs and current inputs may be sampled serially with signal pre-processing applied later if needed to re-align the signals.

In aspects, the electric power data collection device 100 may have a single common voltage reference. In aspects, each of the electric power data collection device 100 may have has its own reference input.

The second processor 112 may be configured to collect continuous waveform data from the inputs. In aspects, the second processor 112 may be configured to collect the sensor readings from the at least one sensor 148. Additionally, the second processor 112 may apply pre-processing to the continuous waveform data and/or the sensor readings from the at least one sensor 148. The preprocessing implemented by the second processor 112 may include scaling, timing adjustments, downsampling, and/or the like to the continuous waveform data and/or the sensor readings from the at least one sensor 148. Further, the second processor 112 may buffer data in a memory 122 that may include the continuous waveform data and/or the sensor readings from the at least one sensor 148.

The second processor 112 may be configured to transfer data to other components the data collection units 102. For example, the second processor 112 may be configured to transfer data to the processor 110. In particular, the second processor 112 may periodically transfer a batch of continuous data to the processor 110 that may include the continuous waveform data and/or the sensor readings from the at least one sensor 148. In this regard, periodically can be for example an n number of 60 Hz cycles, such as every one or two 60 Hz cycles. In one aspect, the second processor 112 may be configured to transfer data to the processor 110 over a bus 124, which may be a local bus, a local Serial Peripheral Interface (SPI) bus, and/or the like.

The processor 110, which may be running embedded Linux, receives this buffer or transfer data from the second processor 112 and the processor 110 adds the transfer data to its accumulation data in the memory 122 or another memory. After accumulating sufficient data (typically 10 seconds worth), the processor 110 may transfer this data to the data analyzers 150 via a connection between the data analyzers 150 and the data collection units 102.

In aspects, the data collection units 102 of the electric power data collection device 100 may capture and send data, such as continuous voltage waveform data, current waveform data, data that includes the sensor readings from the at least one sensor 148, and/or the like to the data analyzer 150 as described. The data collection units 102 may also be configured for other tasks. In some aspects, the second processor 112 and the processor 110 together may provide full power quality monitoring, triggering, and/or the like including standard PQ (Power Quality) metrics such as IEEE 1453 flicker, IEEE 141 flicker, harmonic measurements as per IEEE 519, and/or the like. In addition, the second processor 112 may also compute other derivative signals that may be useful, such as phasor measurement unit (PMU) data, which may be accumulated in the same manner as the raw voltage and current waveforms.

In one aspect, the processor 110 may also record and store standard power quality information in a local memory storage, such as the memory 122. In other aspects, one or more of the features, functionality, and/or the like of the processor 110 may be implemented by the second processor 112; and/or one or more of the features, functionality, and/or the like of the second processor 112 may be implemented by the processor 110. In other aspects, the features, functionality, and/or the like of the processor 110 and the second processor 112 may be combined and implemented in a single processor or additional processors. In one aspect, the features, functionality, and/or the like of the processor 110 and the second processor 112 may be combined and implemented in a processor 130 as illustrated by dashing in FIG. 2.

In aspects, the at least one sensor 148 may collect sensor readings and provide the sensor readings to the electric power data collection device 100, the respective data collection unit 102, the sampling system 108, signal conditioning circuitry 116, and/or the like. In particular, the at least one sensor 148 may be implemented as one or more of a temperature sensor, an air pressure sensor, a humidity sensor, a solar flux sensor, a vibration sensor, and/or the like.

In aspects, the sensor readings from the at least one sensor 148 may be useful for several reasons for monitoring the monitored element 400 such as implementations of the monitored element 400 associated with a utility. Additionally, the sensor readings from the at least one sensor 148 may be useful in the context of analytics. In particular, the sensor readings from the at least one sensor 148 may provide more inputs into the electric power data collection device 100 for the analytics. In one aspect, a utility may implement the at least one sensor 148 outside the monitored element 400, and the monitored element 400 may be paired to the electric power data collection device 100, the data collection unit 102, the data analyzer 150, a similar component, and/or the like.

The at least one sensor 148 may include a housing 146, a power supply 144, a wired or wireless connection 142, and/or the like. The housing 146 may be configured as an enclosure for protecting the at least one sensor 148, the power supply 144, the wired or wireless connection 142, and/or the like from the surrounding environment. The housing 146 may include various features to protect and provide access to the at least one sensor 148, the power supply 144, the wired or wireless connection 142, and/or the like. In one aspect, the housing 146 may include access features, such as a door, to access the at least one sensor 148, connections to the at least one sensor 148, the power supply 144, and/or the like. In aspects, the door may include a hinge structure to allow movement of the door as well as a mechanism to maintain the door in a closed position. Additionally, the housing 146 may include a sensor to monitor access to the housing 146 and/or the at least one sensor 148 and provide sensor outputs as part of the sensor readings. In aspects, the sensor may be a door closure sensor, a magnetic door closure sensor, and/or the like.

The power supply 144 may provide power to the at least one sensor 148 for sensor operation, the wired or wireless connection 142 for communication operation, and/or the like. In aspects, the power supply 144 may be implemented as a battery, a wired power connection to a separate power supply such as a power supply from the data collection unit 102 of the electric power data collection device 100, and/or the like. Battery implementations of the power supply 144 may be configured for long life. For example, battery implementations of the power supply 144 may be configured for up to 10 years of usage of the at least one sensor 148.

The wired or wireless connection 142 may be configured to receive the sensor readings from the at least one sensor 148 and provide the sensor readings to the electric power data collection device 100, the respective data collection units 102, the sampling system 108, the signal conditioning circuitry 116, and/or the like. In one aspect, the wired or wireless connection 142 may include a Wi-Fi (wireless fidelity)/BLE (Bluetooth Low Energy) module that allows for connection to the electric power data collection device 100, the respective data collection unit 102, the sampling system 108, the signal conditioning circuitry 116, and/or the like.

The at least one sensor 148 may be implemented as a temperature sensor configured to measure an ambient temperature of the monitored element 400, the data collection units 102, the electric power data collection device 100, an environment thereof, and/or the like. In aspects, implementation of the at least one sensor 148 as a temperature sensor may include implementations as a thermistor, a thermally sensitive resistor, a negative temperature coefficient (NTC) thermistor, a positive temperature coefficient (PTC) thermistor, a thermocouple, a resistance thermometer, a silicon bandgap temperature sensor, and/or the like.

The at least one sensor 148 may be implemented as an air pressure sensor configured to measure an ambient air pressure of the monitored element 400, the data collection units 102, the electric power data collection device 100, an environment thereof, and/or the like. In aspects, implementation of the at least one sensor 148 as an air pressure sensor may include implementations as microelectromechanical system (MEMS) barometer, a piezoresistive pressure-sensing device, and/or the like.

The at least one sensor 148 may be implemented as a humidity sensor configured to measure an ambient humidity of the monitored element 400, the data collection units 102, the electric power data collection device 100, an environment thereof, and/or the like. In aspects, implementation of the at least one sensor 148 as humidity sensor may include implementations as a capacitive hygrometer, a resistive hygrometer, a thermal hygrometer, a gravimetric hygrometer, optical hygrometer, and/or the like.

The at least one sensor 148 may be implemented as a solar flux sensor configured to measure an ambient solar flux in an environment of the monitored element 400, the data collection units 102, the electric power data collection device 100, and/or the like. In aspects, implementation of the at least one sensor 148 as a solar flux sensor may include implementations as a photodiode, a thermopile pyranometer, photovoltaic pyranometer, a silicon photodiode, a photovoltaic cell, and/or the like.

The at least one sensor 148 may be implemented as a vibration sensor configured to measure an ambient vibration of the monitored element 400, the data collection units 102, the electric power data collection device 100, an environment thereof, and/or the like. In aspects, implementation of the at least one sensor 148 as a vibration sensor may include implementations as a laser accelerometer, a piezoelectric accelerometer, a strain gauge accelerometer, a surface acoustic wave (SAW) accelerometer, a surface micromachined capacitive (MEMS) accelerometer, a potentiometric type accelerometer, and/or the like.

The at least one sensor 148 may be implemented as a wind speed and/or wind direction sensor configured to measure an ambient wind speed and/or wind direction in an environment of the monitored element 400, the data collection units 102, the electric power data collection device 100, and/or the like. In aspects, implementation of the at least one sensor 148 as a wind speed and/or wind direction sensor may include implementations as an ultrasonic wind speed and/or wind direction sensor, a cup anemometer, a vane anemometer, a hot-wire anemometer, a laser doppler anemometer, an ultrasonic anemometer, an acoustic resonance anemometer, a ping-pong ball anemometer, a pressure anemometer, a plate anemometer, a tube anemometer, a pitot tube static anemometer, and/or the like. In aspects, implementation of the at least one sensor 148 as a wind speed and/or wind direction sensor may be configured without moving parts.

The at least one sensor 148 may be implemented as a rainfall/precipitation sensor configured to measure an ambient rainfall/precipitation in an environment of the monitored element 400, the data collection units 102, the electric power data collection device 100, and/or the like. In aspects, implementation of the at least one sensor 148 as a rainfall/precipitation sensor may include implementations as an ultrasonic rain gauge, an acoustic rain gauge, an optical rain gauge, a weighing precipitation gauge, and/or the like. In aspects, implementation of the at least one sensor 148 as a rainfall/precipitation sensor may be configured without moving parts.

The at least one sensor 148 may be implemented to measure other environmental quantities, other physical quantities, and/or the like in an environment of the monitored element 400, the data collection units 102, the electric power data collection device 100, and/or the like. In aspects, implementation of the at least one sensor 148 to measure other environmental quantities, other physical quantities, and/or the like may be configured without moving parts.

In aspects, the data collection units 102 may include a processor 110, such as a DSP (digital signal processor). The processor 110 may be configured for data collection, pre-processing, analytic operations, and/or the like. The data collection units 102 may include a second processor 112. The second processor 112 may be configured for data buffering, communication, and/or the like.

The aspects of the electric power data collection device 100 illustrated in FIG. 9 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 9.

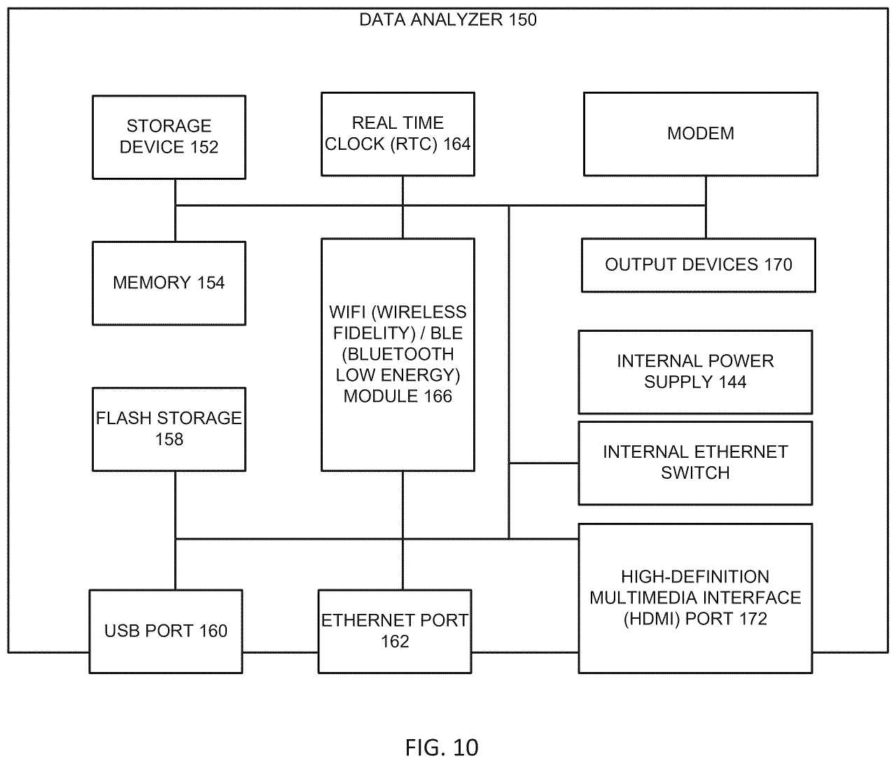

FIG. 10 illustrates a data analyzer according to aspects of the disclosure.

In particular, FIG. 10 illustrates a data analyzer as the second component of the electric power data collection device 100. The data analyzer 150 may be configured to receive periodic data blocks and/or the like from the data collection unit 102. The data analyzer 150 may be configured to receive raw waveform data and/or other data from the data collection unit 102. Additionally, the data analyzer 150 may be configured to provide timestamps, compress the data in a format suitable for storage, store the data in an organized fashion for later retrieval, and/or the like.

In aspects, the data analyzer 150 may be configured to send the data over a network 200 on a communication channel as defined herein to a data lake or a cloud-based analytics system 300. With reference to FIG. 8, if the data analyzer 150 is not connected to the network 200, the data analyzer 150 may be configured to continue to accumulate the data locally in compressed format, periodically transfer the data to a storage device 152, such as a removable storage device. In one or more aspects, the storage device 152 may be implemented as a removable Universal Serial Bus (USB) Flash drive. In this regard, the storage device 152 implemented as a removable Universal Serial Bus (USB) Flash drive may be implemented as a data storage device that includes flash memory with an integrated USB interface.

In this regard, the data analyzer 150 may be configured to allow a user to periodically physically swap the storage device 152. For example, the user may once a week, once a month, and/or the like physically swap the storage device 152. In this regard, the data analyzer 150 may be configured to store continuous waveform data from the monitored element 400 in compressed format. Accordingly, the storage device 152 removed from the data analyzer 150 may have the continuous waveform data from the monitored element 400 stored in the compressed format.

Additionally, the user may provide a replacement implementation of the storage device 152 to the data analyzer 150. In this regard, the replacement implementation of the storage device 152 may be a previously utilized implementation of the storage device 152 that has been previously utilized and the data stored thereon erased. Thereafter, the replacement implementation of the storage device 152 may be utilized by the data analyzer 150 for further data accumulation. For example, the replacement implementation of the storage device 152 may be utilized to store subsequent continuous waveform data from the monitored element 400 stored in the compressed format.

In an aspect, the data analyzer 150 of the electric power data collection device 100 may have a plurality of ports including Bluetooth (Class 1, 2, and Low Energy), Wi-Fi (ad-hoc and Access Point mode), high speed USB, and BLE (for connection to other sensors). For example, the data analyzer 150 may have a USB port 160, such as a USB 3.0 port, which may be exposed at a front panel for a user to insert a high capacity USB Flash drive (typically 1 TB or more), such as the storage device 152. In normal operation, data may be received by the storage device 152 from the data collection units 102 periodically, for example every 10 seconds. The data may be formatted and stored in accumulating files on the local Flash storage 158. If a USB Flash drive is present, such as the storage device 152, this data may be periodically, for example once an hour, copied to that Flash drive, and erased from the local storage. If the USB Flash drive is full, or missing, data may continue to be accumulated on local storage, such as a memory 154, the local Flash storage 158, and/or the like until an empty Flash drive appears.

In one aspect, the data analyzer 150 may have an Ethernet port 162 that may be exposed at the front panel of the data analyzer 150. The Ethernet port 162 may be connected to local area network (LAN), such as a high speed LAN, waveform data and/or the sensor readings from the at least one sensor 148 may be transferred directly from the data analyzer to a cloud-based analytics system 300, in addition to or in lieu of storage on the memory 154, the local Flash storage 158, and/or the like. The Ethernet port 162 may also be used for IEEE 1588 time synchronization, remote device management, other cloud-based data analytics connections, and/or the like.

The data analyzer 150 of the electric power data collection device 100 may implement a real time clock (RTC) 164 that may be configured to keep local time, preferably with a battery backup. The Ethernet port 162 may also be used for connection to a time server for synchronization.

In one aspect, the data analyzer 150 may include a Wi-Fi (wireless fidelity)/BLE (Bluetooth Low Energy) module 166 that allows for connection to a local LAN via Wi-Fi, and local wireless management of the device through BLE using a smartphone application, a tablet application, one or more sensors 148 and/or the like. The data analyzer 150 may be configured to allow spot checks of waveform data, configuration, other management tasks, and/or the like, which may be completed through the BLE link.

In one aspect, the electric power data collection device 100, the data collection unit 102, the data analyzer 150 and/or the like may be adjacent the monitored element 400. As described, the monitored element 400 may be an electrical substation, a solar farm, a wind farm, a Distributed Energy Resource (DER), a portion of a utility transmission infrastructure, a portion of a utility generation infrastructure, one or more circuits, one or more machines, one or more components, and/or the like.

Upon power up, the electric power data collection device 100, the data collection unit 102, the data analyzer 150, and/or the like will begin collecting data from the monitored element 400. If there is no wired or wireless connection, such as a LAN connection, a user will come to the electric power data collection device 100 to swap USB drives.

In one aspect of the disclosed device, the data collected by the data analyzer 150 may be aggregated into 1 second averages, maximums, and/or minimums. Additionally, programmable triggers may cause the cycle readings or raw waveform data to be stored as a waveform capture record in memory 154. The data may also be aggregated into longer term averages, daily profiles, histograms, flicker records, or significant changes, and/or the like. The aggregation sizes for triggered waveforms, transients, and other triggered events may be different and user adjustable. The data may be timestamped from an internal real time clock 164 (RTC) of the electric power data collection device 100. This RTC may be battery-backed or powered via supercapacitor during an outage.

In another aspect of the disclosed device, the electric power data collection device 100 may record and store the triggered waveforms, transients, data aggregations, histograms, daily profiles, and/or the like into internal non-volatile memory. Additionally, the electric power data collection device may also record and store the triggered waveforms, transients, data aggregations, histograms, daily profiles, and/or the like into a cloud system via a wireless connection such as Wi-Fi.

The aspects of the electric power data collection device 100 illustrated in FIG. 10 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 10.

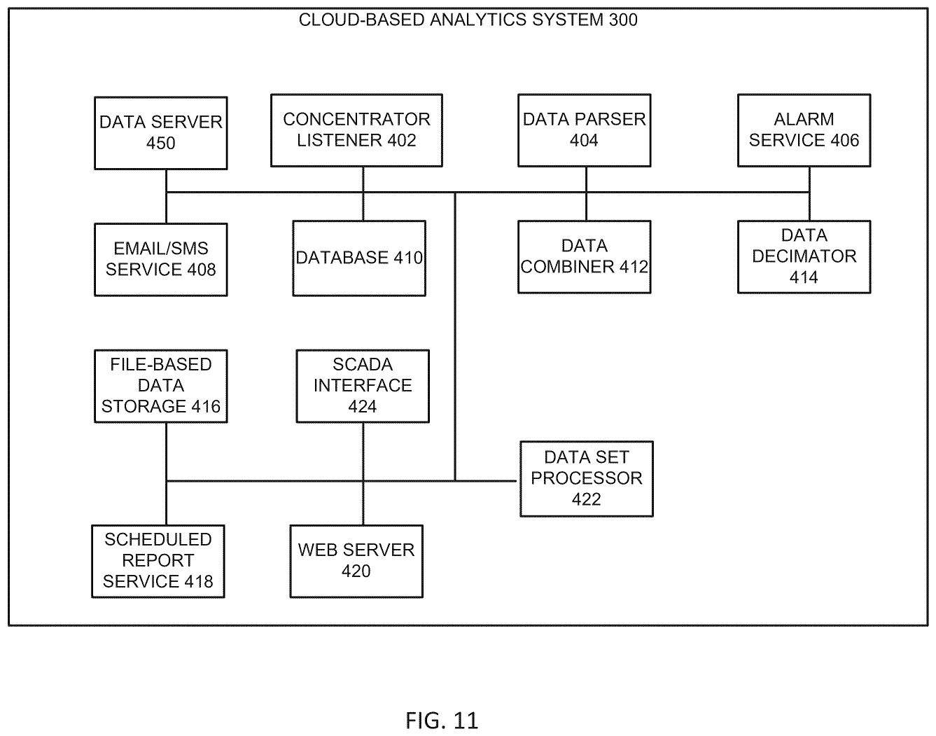

FIG. 11 illustrates an exemplary implementation of a cloud-based server system according to aspects of the disclosure.

In particular, FIG. 11 illustrates an exemplary implementation of the cloud-based analytics system 300 that may be implemented as a cloud-based server system, and may be a collection of virtual machines and processes. The cloud-based analytics system 300 may be configured perform several functions: receive and parse data from electric power data collection device 100 as it streams in to the cloud-based analytics system 300; store all measured values as sent from the electric power data collection device 100; process any alerts from the electric power data collection device 100, including sending immediate message notices, such as email notices, text message notices, application based notices, and/or the like, to any triggered distribution list; provides a map-based graphical display of all the electric power data collection device 100 associated with a specific account; provide graphical and report-based data analysis tools for the user to view and analyze data; provide a control interface to send commands or query status of the electric power data collection device 100, or any other compatible device connected to the electric power data collection device 100 and/or the cloud-based analytics system 300; and/or provide a SCADA system interface to allow an external SCADA master to query information and send commands to the electric power data collection device 100.

The cloud-based analytics system 300 may further include one or more the following components, a data server 450, a concentrator listener 402, a data parser 404, an alarm service 406, an email/SMS service 408, a database 410, a data combiner 412, a data decimator 414, a file-based data storage 416, a scheduled report service 418, a Web server 420, a data set processor 422, a SCADA interface 424, and/or the like.

The user interaction with the cloud-based analytics system 300 may be through a standard web browser. The cloud-based analytics system 300 may utilize any other similar on-demand cloud computing platforms. An aspect may include a collection of Berkeley Software Distribution (BSD) or Linux-based virtual machine servers, including a server for receiving and parsing incoming packets the electric power data collection device 100, storing received measurements, processing and sending alert emails and SMS messages, storing device information, user information, account information, billing information, and/or the like in a SQL database, and providing web hosting (e.g. with Apache) for the user web application. In aspects the servers are connected in a private network, with only the web host including a separate, public network interface (to allow web browser connections). The electric power data collection device 100 may be networked inside a cell carrier private network, with a VPN connection to the data server 450.

The data server 450 may decompress data received from the electric power data collection device 100 and may store the measurement data. Although the data may be stored in a relational database, an aspect uses a binary file format to store individual packets. A separate combiner process may run in the background, reading the small stored packets and combining them into larger chunks (e.g. into a 24 hour chunk).

A web application hosted by the cloud-based analytics system 300 may present a map-based display of all implementations of the electric power data collection device 100 in a user's account. The electric power data collection device 100 may be located at the monitored element 400 manually by the user, or automatically located by using a global navigation satellite system (GNSS) such as GPS, or other positioning information sent by the electric power data collection device 100. A related heat map may be created from the analyzed data by the cloud-based analytics system 300, the electric power data collection device 100, and/or the like to show detected or predicted problem areas graphically overload on a geographic map of the area. Utility-supplied GIS (Graphical Information system) data with the location of utility assets and historical problem locations may be overlaid or combined with the analyzed data on a heat map.

The web page may be used to request the generation of reports in various formats (HTML, CSV, PDF, etc.) These reports may be raw measurements from one or more implementations of the electric power data collection device 100, alert history, account billing information, etc. The reports may be rendered immediately and presented to the user in the browser, or configured to be emailed on a scheduled basis.

The cloud-based analytics system 300 may be configured to present an external interface, to allow a connection to a 3rd party SCADA system or other control system. The external interface may be configured to use a standard SCADA protocol such as DNP, MODBUS over IP, and/or the like and may be configured to present device slave addresses and point maps such that the external SCADA system may poll or send commands to the cloud-based analytics system 300. The electric power data collection device 100 and/or the cloud-based analytics system 300 may parse SCADA messages, responding as needed. These commands and queries may be for data stored on the cloud-based analytics system 300, or require the cloud-based analytics system 300 to issue commands to various implementations of the electric power data collection device 100. For example, an operator may send a SCADA command to operate a component of the monitored element 400 from an outside system. This command may be received by the cloud-based analytics system 300, processed, and relayed to the electric power data collection device 100.

In case of temporary loss in wireless connection, the internal non-volatile memory may allow for later transmission to the cloud-based analytics system 300 when the connection is restored. This set up may also allow for data download by a local device such as a PC, tablet, or smartphone in stand-alone applications. This data may be analyzed directly on the downloading device, saved to a data file, or uploaded to the cloud system later. Once uploaded, the data may be available to cloud users as if it had been sent directly by the local device.

For example, the electric power data collection device 100 may also include the ability to stream data to a local device, such as a personal digital assistant (PDA), smart phone, tablet, PC, and/or the like. The local device may connect to the electric power data collection device 100 using a wireless communication protocol, such as Bluetooth, Wi-Fi, and/or the like. The local device may operate as a master device with the electric power data collection device 100 operating as a slave device. The local device may operate as a central device with the electric power data collection device 100 operating as a peripheral device. The electric power data collection device 100 may be a host of a network Access Point and the local device may join the network. Alternatively, a separate device may be the host of a network Access Point with the local device and electric power data collection device 100 joining the network of the separate device.

The local device may also include an application to query and display the real-time waveforms, harmonics, vector diagrams, and/or the like from the electric power data collection device 100. The local device may download any recorded data from the electric power data collection device 100. The cloud system may present data to a user through the local device, with customizations for device-specific interaction such as swipe and other gestures, pinch to zoom, rotating screen, and/or the like.

The basic data collection system may include the data collection unit 102 and the data analyzer 150, gathering raw bulk waveform data and/or the sensor readings from the at least one sensor 148. In a more advanced embodiment, the waveform data and/or the sensor readings from the at least one sensor 148 may be periodically fed into the cloud-based analytics system 300, which may use this data, possibly in combination with outside information, data, measurements, and/or the like such as known system device operation (e.g. reclosers, circuit breakers, and/or the like), equipment failures, and/or the like. In aspects, the electric power data collection device 100 and/or a component of the electric power data collection device 100 may collect the outside information, data, measurements, and/or the like consistent with the collection of the waveform data.

The waveform data, the sensor readings from the at least one sensor 148, the outside information, data, measurements, and/or the like may be utilized to train the cloud-based analytics system 300, and/or the like to create waveform signatures, which may be utilized to predict future events. These waveform signatures, one or more algorithms, and/or the like may be loaded onto a device, the electric power data collection device 100, the cloud-based analytics system 300, and/or the like either manually, or automatically. The device, the electric power data collection device 100, the cloud-based analytics system 300, and/or the like may implement these waveform signatures, one or more neural networks, one or more algorithms, and/or the like to create alerts when these patterns are detected. In aspects, the waveform signatures, one or more neural networks, one or more algorithms may be generated, trained, implemented, and/or the like utilizing artificial intelligence and/or machine learning as defined herein. The alerts may be transferred to the data analyzer 150 and upstream to the cloud-based analytics system 300, a cloud-based, and/or other system to send email notifications, SMS notifications, Supervisory Control And Data Acquisition (SCADA) notifications, and/or other notifications as needed.

The electric power data collection device 100 and/or the cloud-based analytics system 300 may also be connected to a SCADA system via Distributed Network Protocol 3 (DNP3), MODBUS, IEC 61850, and/or other protocol. It can operate as a SCADA remote terminal unit (RTU), making data collection card data available to a SCADA master, and sending unsolicited reports by exception. In most cases, raw waveform data would not be suitable for SCADA transfer, rather the data analyzer 150 would send aggregate measures the data collection unit 102 such as RMS voltage, current, real power, harmonic distortion, and/or the like. In some embodiments, the data collection unit 102 or the data analyzer 150 may have relay or digital inputs and outputs controllable by the SCADA system, to facilitate SCADA switching or operation of external devices such as relays, contactors, breakers, and/or the like, in parallel with the devices primary function as a data collection system.

In some embodiments, a networked device may send periodic data to a cloud based system such as PMI's PQ Canvass system. Some or all of the collected data may be presented to the user via the web interface of the cloud system, either as raw waveforms, or as computed PQ information.

In one or more aspects, the electric power data collection device 100, the data collection unit 102, the data analyzer 150, and/or the like may include communication ports for interfacing with external sensors. The communication ports may be implemented utilizing any known technology including RS-485, Ethernet, RS-232, wireless links, and/or the like. In one aspect, the external ports may include a SCADA port.

In one or more aspects, the electric power data collection device 100, the data collection unit 102, the data analyzer 150, and/or the like may include embedded technology to control cell modems, satellite modems, process data from external ports, interface the monitored element 400, interface the cloud-based analytics system 300, perform real-time voltage, current, and power calculations, and/or the like the like.

The aspects of the electric power data collection device 100 illustrated in FIG. 11 and described therewith, may optionally be implemented in any other aspects of the electric power data collection device 100 illustrated in the other figures and described therewith. Further, the aspects of the electric power data collection device 100 illustrated in the other figures and described therewith may optionally be implemented in the aspects of the electric power data collection device 100 illustrated in FIG. 11.

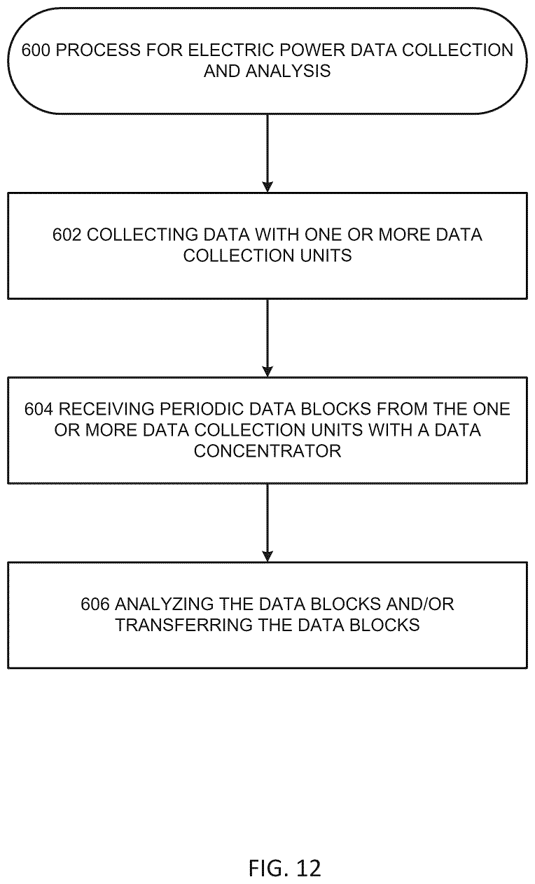

FIG. 12 illustrates a process for electric power data collection and analysis according to aspects of the disclosure.

In particular, FIG. 12 illustrates a process for electric power data collection and analysis 600 which may include any one or more the features described herein. The process for electric power data collection and analysis 600 may be implemented by any component of the electric power data collection device 100. The process for electric power data collection and analysis 600 may be implemented by software.

The process for electric power data collection and analysis 600 may include collecting data with data collection unit 602. In particular, the collecting data with data collection unit 602 may include collecting data as described herein by the data collection unit 102. For example, the collecting data with data collection unit 602 may include receiving an analog signal (line voltage, current, or the like), conditioning the signal, digitizing the signal, calculating a measurement of various factors (RMS, total harmonic distortion (THD), etc.), applying an averaging and conditioning of the measurement, and/or the like.

The process for electric power data collection and analysis 600 may include receiving periodic data blocks from the data collection unit with a data analyzer 604. In particular, the receiving periodic data blocks from the data collection unit with a data analyzer 604 may include receiving periodic data blocks from the data collection unit 102 with the data analyzer 150 as described herein.

The process for electric power data collection and analysis 600 may include analyzing the data blocks and/or transferring the data blocks 606. In particular, the analyzing the data blocks and/or transferring the data blocks 606 may include any of the analysis of the data blocks or transfer of the data blocks as described herein. For example, the analyzing the data blocks and/or transferring the data blocks 606 may include determining whether a trigger is met. If the trigger is met (yes), then analyzing the data blocks and/or transferring the data blocks 606 may send message to the cloud-based analytics system 300 or one or more other components as described herein.

One EXAMPLE: an apparatus includes at least one transducer configured to measure an electrical parameter of a monitored element. The apparatus in addition includes a data collection unit configured to collect data that comprises at least the electrical parameter measured by the at least one transducer. The apparatus moreover includes a data analyzer configured to receive periodic data blocks from the data collection unit that comprises the data collected by the data collection unit. The apparatus also includes an elongated body containing the at least one transducer, the data collection unit, the a data analyzer. The apparatus further includes where the electrical parameter comprises at least one of the following: voltage, current, and/or power. The apparatus in addition includes where the elongated body is configured to fit inside a space of an enclosure.

The above-noted EXAMPLE may further include any one or a combination of more than one of the following EXAMPLES: The apparatus of the above-noted EXAMPLE where the elongated body has a cylindrical cross-section. The apparatus of the above-noted EXAMPLE includes: at least one connectorized input for measuring voltage located at a first end of the elongated body; and at least one connectorized input for measuring current located at a second end of the elongated body, opposite to the first end. The apparatus of the above-noted EXAMPLE where the at least one connectorized input for measuring voltage and the at least one connectorized input for measuring current extend in a same direction as the elongated body elongates. The apparatus of the above-noted EXAMPLE where the apparatus operates at a voltage of 300 V or 600 V. The apparatus of the above-noted EXAMPLE where the data analyzer is configured to send the data through a network to a cloud-based analytics system. The apparatus of the above-noted EXAMPLE where the apparatus is connected to a local device. The apparatus of the above-noted EXAMPLE where the elongated body comprises a first dimension along a lateral axis and the elongated body comprises a second dimension along a longitudinal axis; and where the second dimension is greater than the first dimension. The apparatus of the above-noted EXAMPLE where the second dimension is 1.5-5 times greater than the first dimension.

One EXAMPLE: an apparatus includes at least one transducer configured to measure an electrical parameter of a monitored element. The apparatus in addition includes a data collection unit configured to collect data that comprises at least the electrical parameter measured by the at least one transducer. The apparatus moreover includes a data analyzer configured to receive periodic data blocks from the data collection unit that comprises the data collected by the data collection unit. The apparatus also includes an elongated body containing the at least one transducer, the data collection unit, the a data analyzer. The apparatus further includes where the electrical parameter comprises at least one of the following: voltage, current, and/or power. The apparatus in addition includes where the elongated body comprises a first dimension along a lateral axis and the elongated body comprises a second dimension along a longitudinal axis. The apparatus moreover includes where the second dimension is greater than the first dimension.

The above-noted EXAMPLE may further include any one or a combination of more than one of the following EXAMPLES: The apparatus of the above-noted EXAMPLE where the elongated body has a cylindrical cross-section. The apparatus of the above-noted EXAMPLE includes: at least one connectorized input for measuring voltage located at a first end of the elongated body; and at least one connectorized input for measuring current located at a second end of the elongated body, opposite to the first end. The apparatus of the above-noted EXAMPLE where the at least one connectorized input for measuring voltage and the at least one connectorized input for measuring current extend in a same direction as the elongated body elongates. The apparatus of the above-noted EXAMPLE where the apparatus operates at a voltage of 300 V or 600 V. The apparatus of the above-noted EXAMPLE where the data analyzer is configured to send the data through a network to a cloud-based analytics system. The apparatus of the above-noted EXAMPLE where the apparatus is connected to a local device. The apparatus of the above-noted EXAMPLE where the elongated body is configured to fit inside a space of an enclosure. The apparatus of the above-noted EXAMPLE where the second dimension is 1.5-5 times greater than the first dimension.

Accordingly, the disclosure has disclosed solutions for providing a novel data acquisition and collection device, system, and/or process coupled with optional cloud-based data collection and analysis features. The disclosed device, system, and/or process provides for the collection of large datasets from the electric power grid to feed into ML training systems, Al training systems, and/or the like and optionally provides a mechanism to apply new algorithms back to the disclosed device, system, and/or process to enhance data collection and triggering mechanisms.

What is claimed is:

1. An apparatus for electric power data collection and analysis comprising:
at least one transducer configured to measure an electrical parameter of a monitored element;
a data collection unit configured to collect data that comprises at least the electrical parameter measured by the at least one transducer;
a data analyzer configured to receive periodic data blocks from the data collection unit that comprises the data collected by the data collection unit; and
an elongated body containing the at least one transducer, the data collection unit, the a data analyzer,
wherein the electrical parameter comprises at least one of the following: voltage, current, and/or power; and
wherein the elongated body is configured to fit inside a space of an enclosure.

2. The apparatus for electric power data collection and analysis of claim 1, wherein the elongated body has a cylindrical cross-section.

3. The apparatus for electric power data collection and analysis of claim 1, further comprising:
at least one connectorized input for measuring voltage located at a first end of the elongated body; and
at least one connectorized input for measuring current located at a second end of the elongated body, opposite to the first end.

4. The apparatus for electric power data collection and analysis of claim 3, wherein the at least one connectorized input for measuring voltage and the at least one connectorized input for measuring current extend in a same direction as the elongated body elongates.

5. The apparatus for electric power data collection and analysis of claim 1, wherein the apparatus operates at a voltage of 300 V or 600 V.

6. The apparatus for electric power data collection and analysis of claim 1, wherein the data analyzer is configured to send the data through a network to a cloud-based analytics system.

7. The apparatus for electric power data collection and analysis of claim 1, wherein the apparatus is connected to a local device.

8. The apparatus for electric power data collection and analysis of claim 1
wherein the elongated body comprises a first dimension along a lateral axis and the elongated body comprises a second dimension along a longitudinal axis; and
wherein the second dimension is greater than the first dimension.

9. The apparatus for electric power data collection and analysis of claim 1 wherein the second dimension is 1.5-5 times greater than the first dimension.

10. An apparatus for electric power data collection and analysis comprising:
at least one transducer configured to measure an electrical parameter of a monitored element;
a data collection unit configured to collect data that comprises at least the electrical parameter measured by the at least one transducer;
a data analyzer configured to receive periodic data blocks from the data collection unit that comprises the data collected by the data collection unit; and
an elongated body containing the at least one transducer, the data collection unit, the a data analyzer,
wherein the electrical parameter comprises at least one of the following: voltage, current, and/or power; and
wherein the elongated body comprises a first dimension along a lateral axis and the elongated body comprises a second dimension along a longitudinal axis; and
wherein the second dimension is greater than the first dimension.

11. The apparatus for electric power data collection and analysis of claim 10, wherein the elongated body has a cylindrical cross-section.

12. The apparatus for electric power data collection and analysis of claim 10, further comprising:
at least one connectorized input for measuring voltage located at a first end of the elongated body; and
at least one connectorized input for measuring current located at a second end of the elongated body, opposite to the first end.

13. The apparatus for electric power data collection and analysis of claim 12, wherein the at least one connectorized input for measuring voltage and the at least one connectorized input for measuring current extend in a same direction as the elongated body elongates.

14. The apparatus for electric power data collection and analysis of claim 10, wherein the apparatus operates at a voltage of 300 V or 600 V.

15. The apparatus for electric power data collection and analysis of claim 10, wherein the data analyzer is configured to send the data through a network to a cloud-based analytics system.

16. The apparatus for electric power data collection and analysis of claim 10, wherein the apparatus is connected to a local device.

17. The apparatus for electric power data collection and analysis of claim 10 wherein the elongated body is configured to fit inside a space of an enclosure.

18. The apparatus for electric power data collection and analysis of claim 10 wherein the second dimension is 1.5-5 times greater than the first dimension.
